(19) United States
(12) Patent Application Publication
(10) Pub. No.: US 2009/0246652 A1
(43) Pub. Date: Oct. 1, 2009

(54) COLOR FILTER AND METHOD OF FABRICATING THE SAME

(76) Inventors: Pin-Chen CHEN, Tapei City (TW); Hui-Lung KUO, Taipei City (TW); Chih-Ho CHIU, Taipei City (TW); Liang-Bin YU, Taipei County (TW)

Correspondence Address: BIRCH STEWART KOLASCH & BIRCH, PO BOX 747, FALLS CHURCH, VA, 22040-0747, US

(21) Appl. No.: 12/479,619

(22) Filed: Jun. 5, 2009

Related U.S. Application Data
(62) Division of application No. 11/176,261, filed on Jul. 8, 2005.

(30) Foreign Application Priority Data
Dec. 30, 2004 (TW) 93141344

(51) Int. Cl. G03F 1/00

(52) U.S. Cl. 430/7

(57) ABSTRACT

A color filter having a bi-layer metal grating is formed by nanoimprint lithography. Nanoimprint lithography, a low cost technology, includes two alternatives, i.e., hotembossing nanoimprint lithography and UV-curable nanoimprint lithography. Manufacture steps comprises providing a substrate with a polymer material layer disposed thereon. A plurality of lands and grooves are formed in the polymer material layer, and a first metal layer and a second metal layer are disposed on the surfaces of the lands and grooves, respectively. Finally, a color filter having a bi-layer metal grating is obtained.

### CROSS REFERENCE TO RELATED APPLICATIONS

This application is a Divisional of co-pending application Ser. No. 11/76,261 filed Jul. 8, 2005, and for which priority is claimed under 35 U.S.C. § 120; and this application claims priority of Application No. 93141344, filed in Taiwan, Republic of China on Dec. 30, 2004, the entire contents of which are hereby incorporated by reference.

### BACKGROUND

The present invention relates to a color filter and method of fabricating the same, and more particularly to a color filter having a bi-layer metal grating.

Color filter, a main component in an LCD device, converts white light to red, green, and blue light. Methods of fabrication comprise dyeing, printing, electrodeposition, or pigment dispersal. Pigment dispersal and dyeing methods are both popularly used.

FIG. 1 shows a pigment dispersed method, comprising coating of photoresist, pre-baking, exposure, development, and post-baking. A color array, including red, green, and blue films, is formed by repeating the steps three times. The red, green, and blue films have different thicknesses to achieve agreement of light intensity. In addition to being complex and low yield, the method is also limited by low color saturation, non-uniform thickness.

As well, Dyeing offers only low resistant to heat and chemicals. Neither method significantly improves color purity.

For a color filter, optical properties, compatibility with subsequent process, and reliability are all priorities, with optical properties such as transmission aid color saturation being most important.

High transmission requires less intensity from backlight, thereby saving power. Red, green, and blue transmittance percentages are required to approach 85%, 75%, and 75%, respectively.

High color saturation can be achieved by coupling a color filter with a backlight. The backlight may be a cold cathode fluorescent lamp. FIG. 2 is a chart showing the transmission spectrum for a cold cathode fluorescent lamp. However, as shown in FIG. 2, there are two undesired transmission peaks at 490 nm and 580 nm, resulting in a significant loss of color saturation. In addition, a conventional color filter, as shown in FIG. 3, can't effectively eliminate the described transmitted light.

Accordingly, a simplified method for fabricating a color filter capable of enhancing color saturation is required.

### SUMMARY

A method of fabricating a sub-wavelength structure was proposed by Chou et al. in 1999, utilizing thermal nanoimprint lithography. In addition, a method of fabricating a nanostructure has been proposed by Molecular Imprints, Inc. using step and flash imprint lithography.

An embodiment of a method of fabricating a color filter comprises photoresist layers having different thicknesses being formed on a substrate. The substrate is glass or plastic and the photoresist comprises photosensitive polymer material or polymethyl methacrylate (PMMA).

A mask or mold having suitable period, depth, and aspect ratio is used in hot-embossing nanoimprint lithography or UV-curable nanoimprint lithography, transferring the pattern to the photoresist layers.

Metal layers are disposed on the photoresist layers by sputtering or vacuum deposition, thereby a bi-layer metal grating with a desired spacing between the metal layers is obtained. The photoresist's index of refraction exceeds that of the metal layers, reducing reflected light.

In addition, optical properties of the color filter of the embodiment are simulated by a commercial application, the Gsolver Diffraction Grating Analysis Program, based on RCWA (rigorous coupled wave analysis), a commercial application developed by Grating Solver Development Company.

The color filter of the embodiment, having a bi-layer metal grating, provides 10 nm spacing between the metal layers, a grating period of 100 to 400 nm, and a thickness of metal layers from 30 to 200 nm. By altering the spacing between the metal layers, grating period, and thickness of metal layers, the problems disclosed can be solved and transmission enhanced up to 85%.

The bi-layer metal grating of the embodiment has a total thickness of less than 500 nm and difference in metal layers is less than 100 nm. In addition to simplified process the bi-layer metal grating provides smooth surfaces to reduce scattering, with increased brightness.

The color filter coupled to a polarizer can be used to polarized light and display a color image. The polarizer may be disposed on any side of the substrate.

The color filter of the embodiment may be applied to reflective, projective, or organic light emitting display devices.

A detailed description is given in the following embodiments with reference to the accompanying drawings.

### DESCRIPTION OF THE DRAWINGS

A color filter and method of fabricating the same will become more fully understood from the detailed description given herein below and the accompanying drawings, given by way of illustration only and thus not intended to be limitative of the invention.

FIG. 1 is a flowchart of a conventional method for fabricating a color filter.

FIG. 2 is a chart showing the transmission spectrum of a cold cathode fluorescent lamp.

FIG. 3 is a chart showing the transmission spectrum of a conventional color filter.

FIGS. 4A to 4G are cross-sections of an embodiment of a method for fabricating a color filter.

FIG. 4H is a cross-section of an embodiment of a color filter.

FIG. 5 is a chart showing the transmission spectrum of a color filter.

FIGS. 6A to 6G are cross-sections of an embodiment of a method for fabricating a color filter.

FIG. 6H is a cross-section of an embodiment of a color filter.

FIG. 7 is a chart showing the transmission spectrum of a color filter.

FIGS. 8A to 8G are cross-sections of an embodiment of a method for fabricating a color filter.

FIG. 8H is a cross-section of an embodiment of a color filter.

FIG. 9 is a chart showing the transmission spectrum of a color filter.

FIGS. 10A to 10G are cross-sections of an embodiment of a method for fabricating a color filter.

FIG. 10H is a cross-section of an embodiment of a color filter.

FIG. 11 is a chart showing the transmission spectrum of a color filter.

FIGS. 12A to 12G are cross-sections of an embodiment of a method for fabricating a color filter.

FIG. 12H is a cross-section of an embodiment of a color filter.

FIG. 13 is a chart showing the transmission spectrum of a color filter.

FIGS. 14A to 14G are cross-sections of an embodiment of a method for fabricating a color filter.

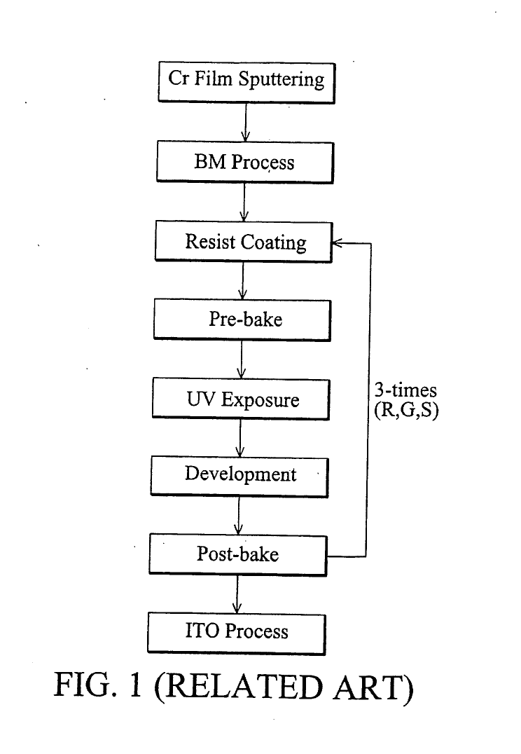

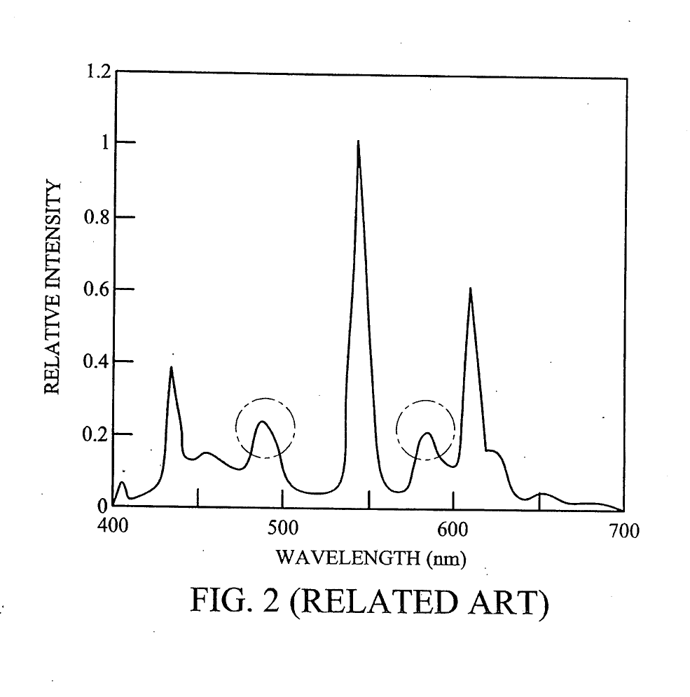

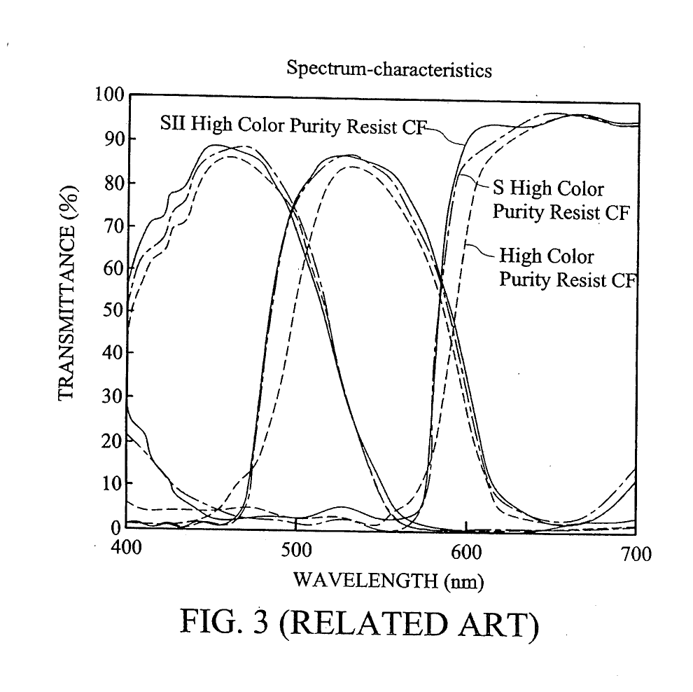

### DETAILED DESCRIPTION

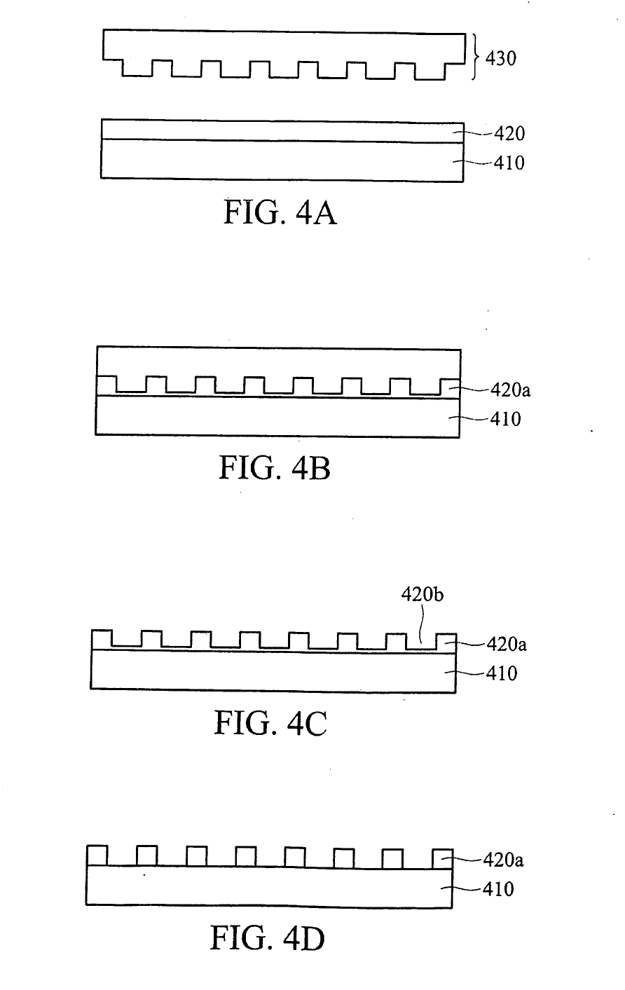

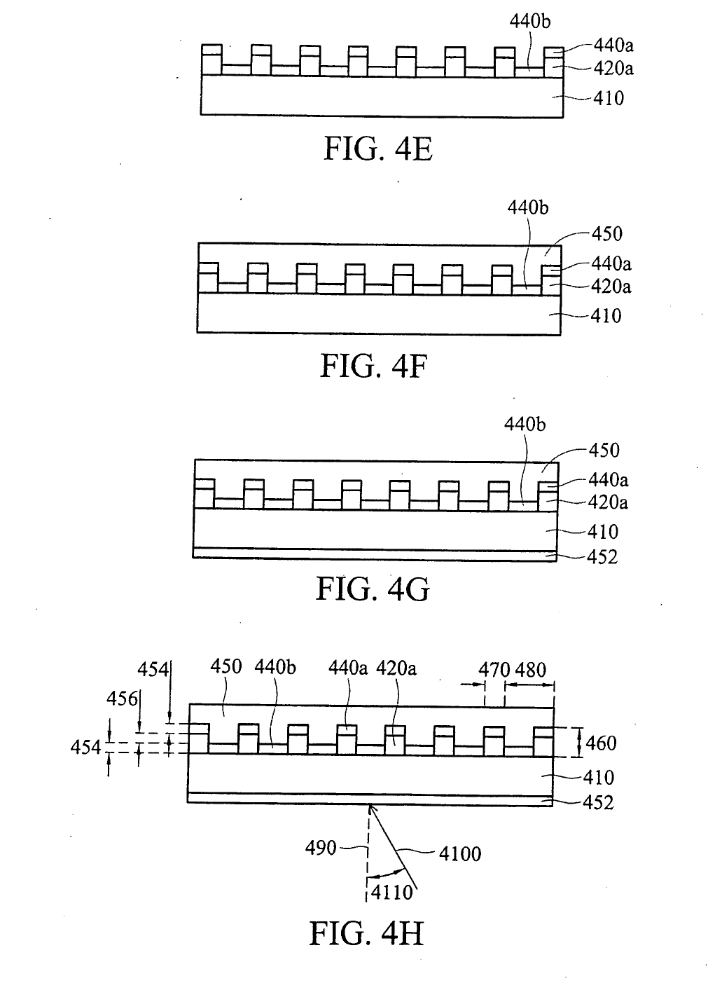

FIGS. 4 to 13 show embodiments of a method of fabricating a color filter using hot-embossing nanoimprint lithography.

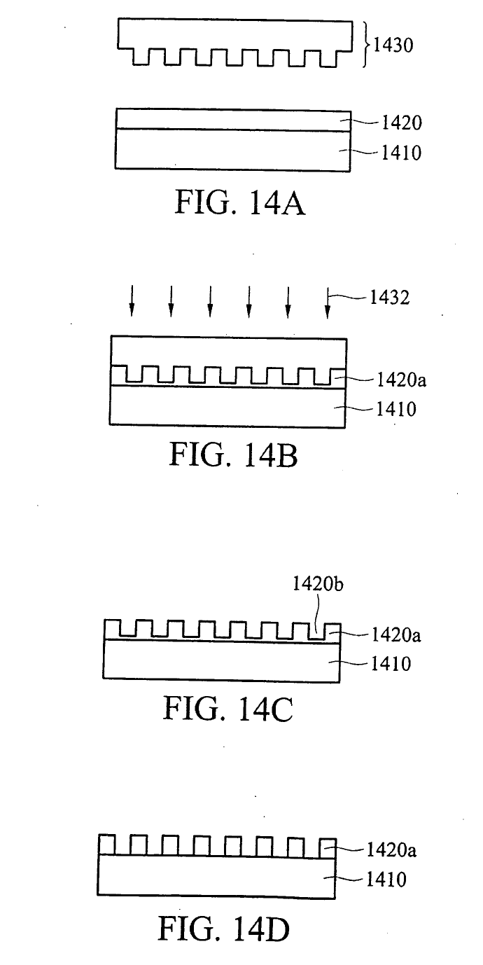

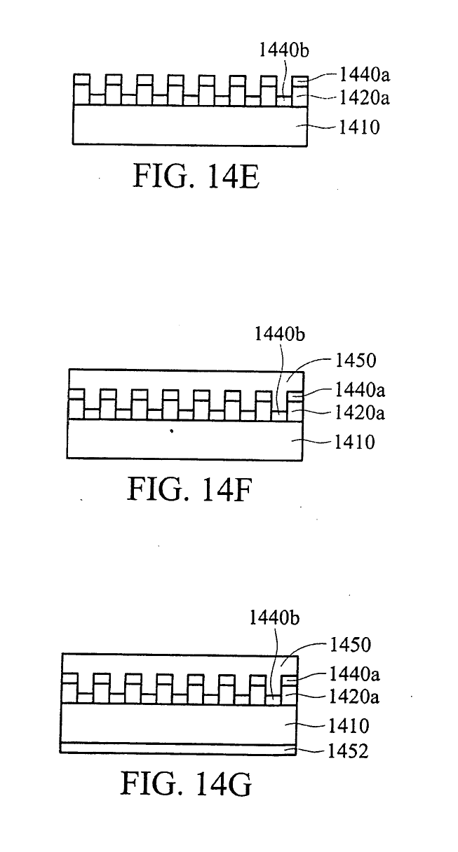

FIGS. 14A to 14G show an embodiment of a method of fabricating a color filter using UV-curable nanoimprint lithography.

In FIG. 4A, a substrate 410, such as a glass substrate, with a polymer layer 420 formed thereon is provided. The polymer layer 420 may be polymethyl methacrylate (PMMA).

In FIGS. 4A to 4B, a mold 430 having a pattern of microstructure is pressed into the polymer layer 420 and the polymer layer 420 is heated above a glass transition temperature thereof, thereby transferring the pattern to the polymer layer 420.

After removal of the mold 430, a plurality of lands 420a and grooves 420b are formed in the polymer layer 420, as shown in FIG. 4C.

In FIG. 4D, reactive ion etching removes residual portions of the polymer layer 420 from the bottom of the grooves 420b, thereby exposing surfaces of the substrate 410.

In FIG. 4E, a first metal layer 440a and second metal layer 440b are concurrently formed on the lands 420a and grooves 420b, respectively, using sputtering or vacuum deposition. The first metal layer 440a and second metal layer 440b may be gold (Au).

In FIG. 4F, a dielectric layer 450 is formed on the first metal layer 440a and second metal layer 440b.

In FIG. 4G, a polarizer 452 is disposed under the substrate 410.

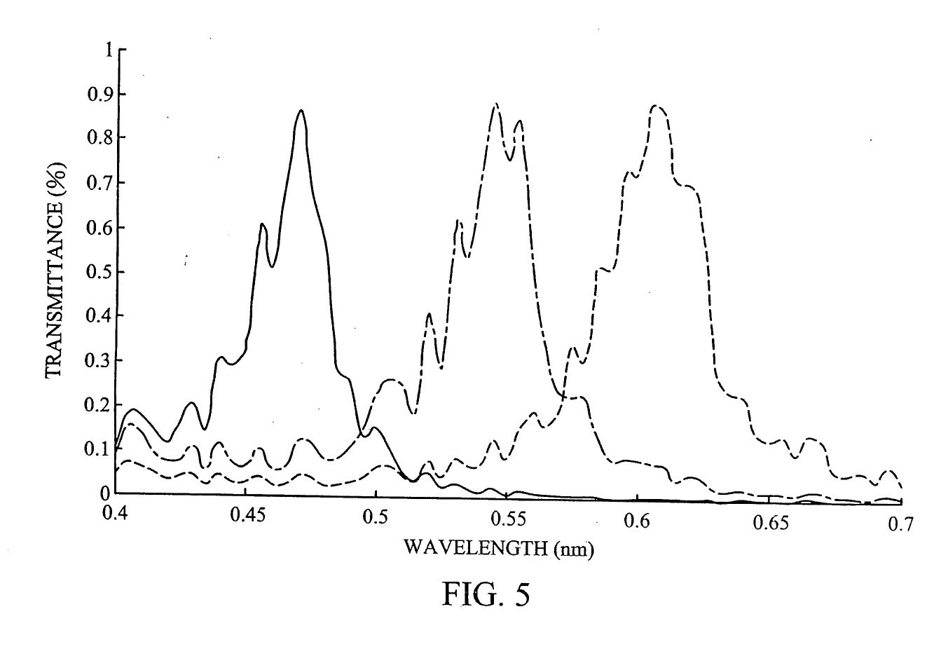

In addition, optical properties of the color filter of the embodiment are simulated by a commercial application called Gsolver. FIG. 5 is a chart showing the transmission spectrum for the color filter shown in FIG. 4H with an exemplary incident light 4100. The incident light 4100 has a wavelength between 400 and 700 nm, and an incident angle 4110. The substrate 410 has a thickness of 1000 micrometers. One land 420a and one groove 420b have a total width 480 of 250 nm. The lands 420a have a uniform width 470 of 100 nm. The first metal layer 440a and second metal layer 440b have a uniform thickness 454, comprising 90, 70, or 65 nm. The first metal layer 440a has a relative height 456 exceeding that of the second metal layer 440b, of 100, 135, or 160 nm.

As shown in FIG. 5, the transmission peaks occur at 470 (blue), 550 (green), and 610 nm (red), respectively.

In this embodiment, the color filter provides significantly improved light filtering, thereby increasing the purity of light.

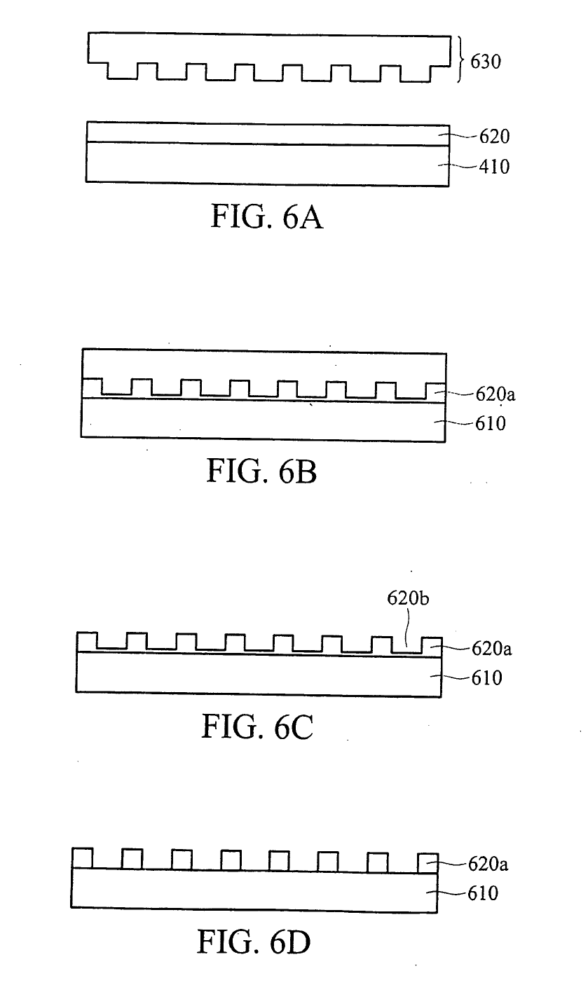

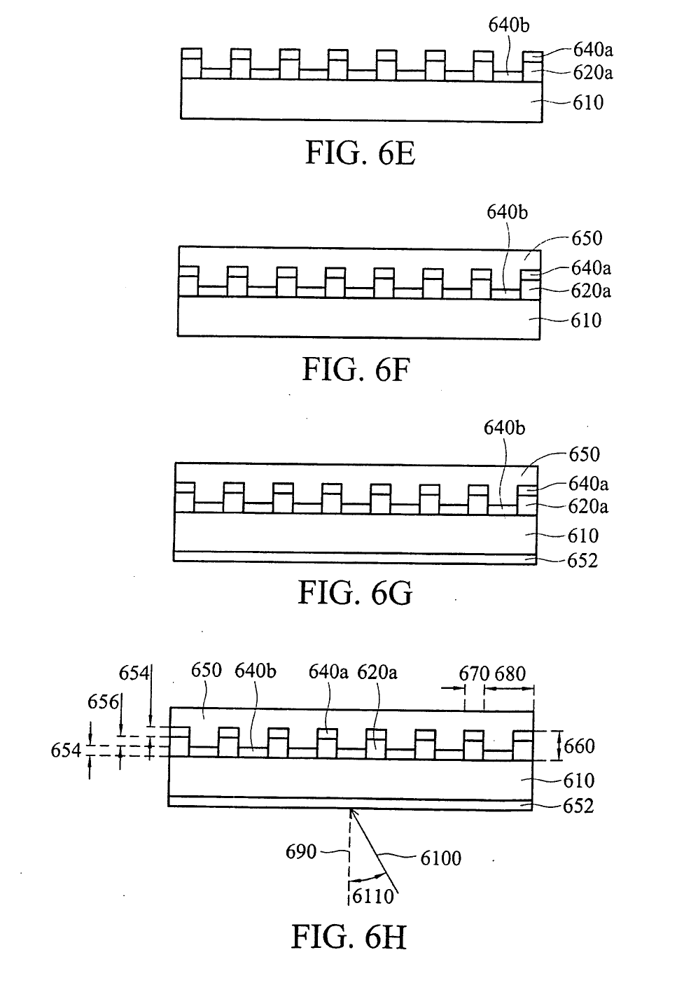

In FIG. 6A, a substrate 610, such as a glass substrate, with a polymer layer 620 formed thereon is provided. The polymer layer 620 may be polymethyl methacrylate (PMMA).

In FIGS. 6A to 6B, a mold 630 having a pattern of microstructure is pressed into the polymer layer 620 and the polymer layer 620 is heated above a glass transition temperature thereof, thereby transferring the pattern to the polymer layer 620.

After removal of the mold 630, a plurality of lands 620a and grooves 620b are formed in the polymer layer 620, as shown in FIG. 6C.

In FIG. 6D, reactive ion etching removes residual portions of the polymer layer 620 from the bottom of the grooves 620b, thereby exposing surfaces of the substrate 610.

In FIG. 6E, a first metal layer 640a and second metal layer 640b are concurrently formed on the lands 620a and grooves 620b, respectively, using sputtering or vacuum deposition. The first metal layer 640a and second metal layer 640b may be aluminum (Al).

In FIG. 6F, a dielectric layer 650 is formed on the first metal layer 640a and second metal layer 640b.

In FIG. 6G, a polarizer 652 is disposed under the substrate 610.

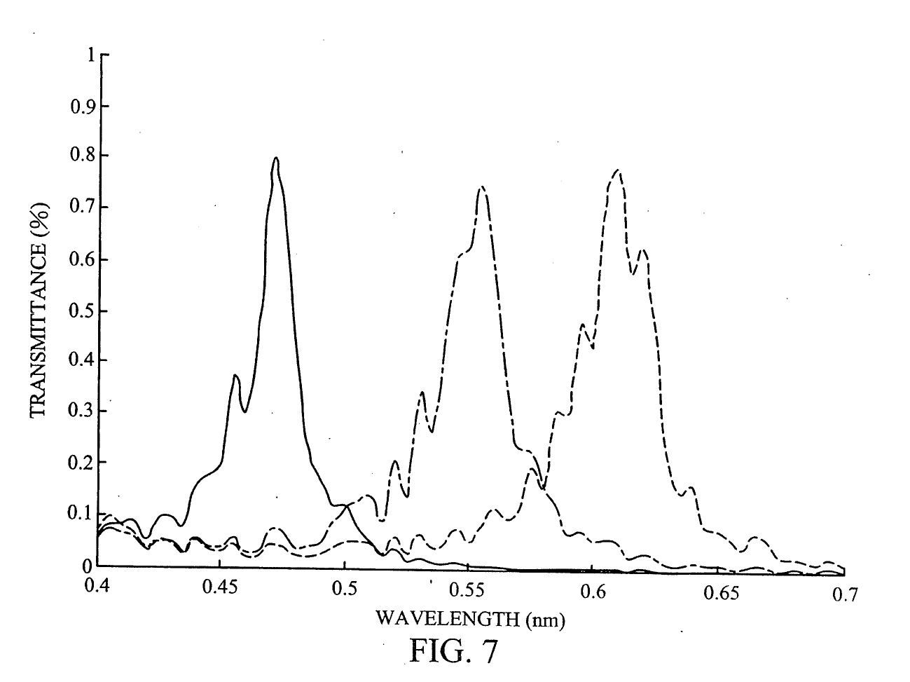

In addition, optical properties of the color filter of the embodiment are simulated by a commercial application called Gsolver. FIG. 7 is a chart showing the transmission spectrum for the color filter shown in FIG. 6H with an exemplary incident light 6100. The incident light 6100 has a wavelength between 400 and 700 nm, and an incident angle 6110. The substrate 610 has a thickness of 1000 micrometers. One land 620a and one groove 620b have a total width 680 of 250 nm. The lands 620a have a uniform width 670 of 100 nm. The first metal layer 640a and second metal layer 640b have a uniform thickness 654, of 60, 45, or 40 nm. The first metal layer 640a has a relative height 656 exceeding that of the second metal layer 640b, and the relative height 656 may be 125, 160, or 184 nm.

As shown in FIG. 7, transmission peaks occur at 470 (blue), 550 (green), and 610 nm (red), respectively.

In this embodiment, the metal layers are Al. The color filter performs better in filtering light and producing high color purity light while the transmission is only about 80%.

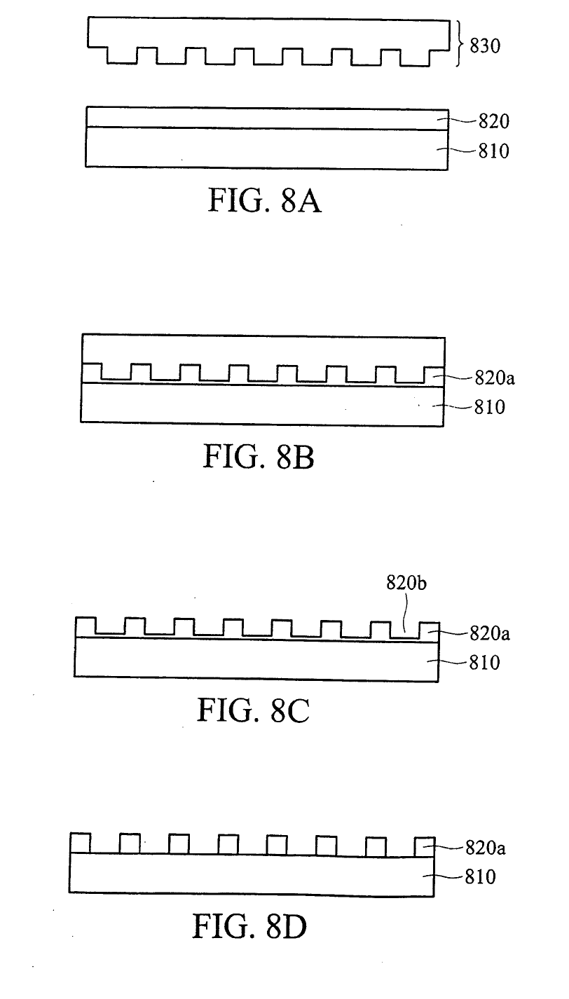

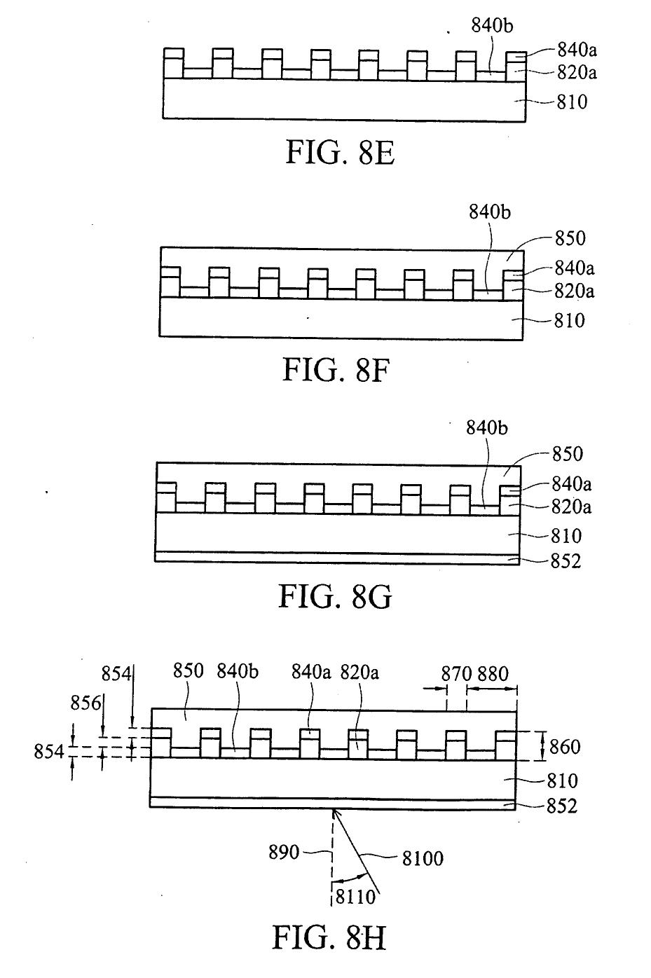

In FIG. 8A, a substrate 810, such as a glass substrate, with a polymer layer 820 formed thereon is provided. The polymer layer 820 may be polymethyl methacrylate (PMMA).

In FIGS. 8A to 8B, a mold 830 having a pattern of microstructure is pressed into the polymer layer 820 and the polymer layer 820 is heated above a glass transition temperature thereof, thereby transferring the pattern to the polymer layer 820.

After removal of the mold 830, a plurality of lands 820a and grooves 820b are formed in the polymer layer 820, as shown in FIG. 8C.

In FIG. 8D, reactive ion etching removes residual portions of the polymer layer 820 from the bottom of the grooves 820b, thereby exposing surfaces of the substrate 810.

In FIG. 8E, a first metal layer 840a and second metal layer 840b are concurrently formed on the lands 820a and grooves 820b, respectively, using sputtering or vacuum deposition. The first metal layer 840a and second metal layer 840b may be silver (Ag).

In FIG. 8F, a dielectric layer 850 is formed on the first metal layer 840a and second metal layer 840b.

In FIG. 8G, a polarizer 852 is disposed under the substrate 810.

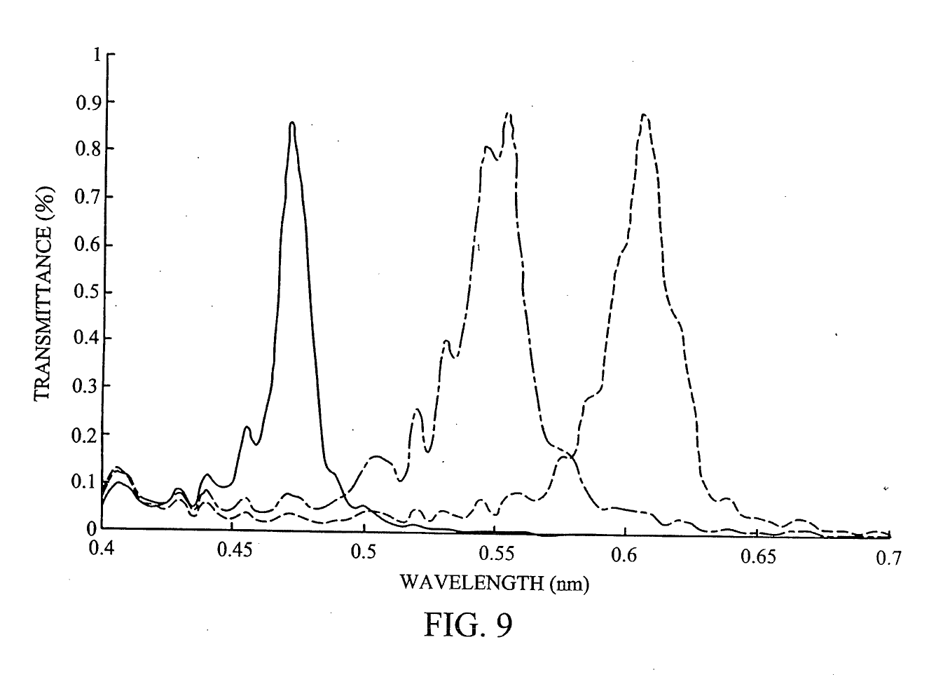

In addition, optical properties of the color filter of the embodiment are simulated by a commercial application called Gsolver. FIG. 9 is a chart showing the transmission spectrum for the color filter shown in FIG. 8H with an exemplary incident light 8100. The incident light 8100 has a wavelength between 400 and 700 nm, and an incident angle 8110. The substrate 810 has a thickness of 1000 micrometers. One land 820a and one groove 820b have a total width 880 of 250 nm. The lands 820a have a uniform width 870 of 100 nm. The first metal layer 840a and second metal layer 840b have a uniform thickness 854, of 120, 80, or 80 nm. The first metal layer 840a has a relative height 856 exceeding that of the second metal layer 840b, of 100, 136, or 160 nm.

As shown in FIG. 9, the transmission peaks occur at 470 (blue), 550 (green), 610 nm (red), respectively.

In this embodiment, the metal layers are Ag. The color filter not only performs better in filtering light but also produces high color purity light. Additionally. each color light has a transmission over 85%.

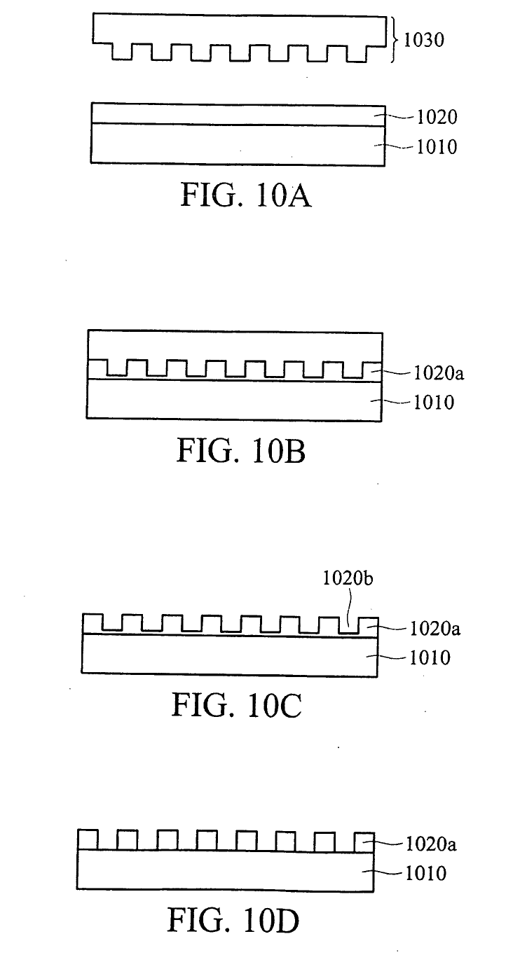

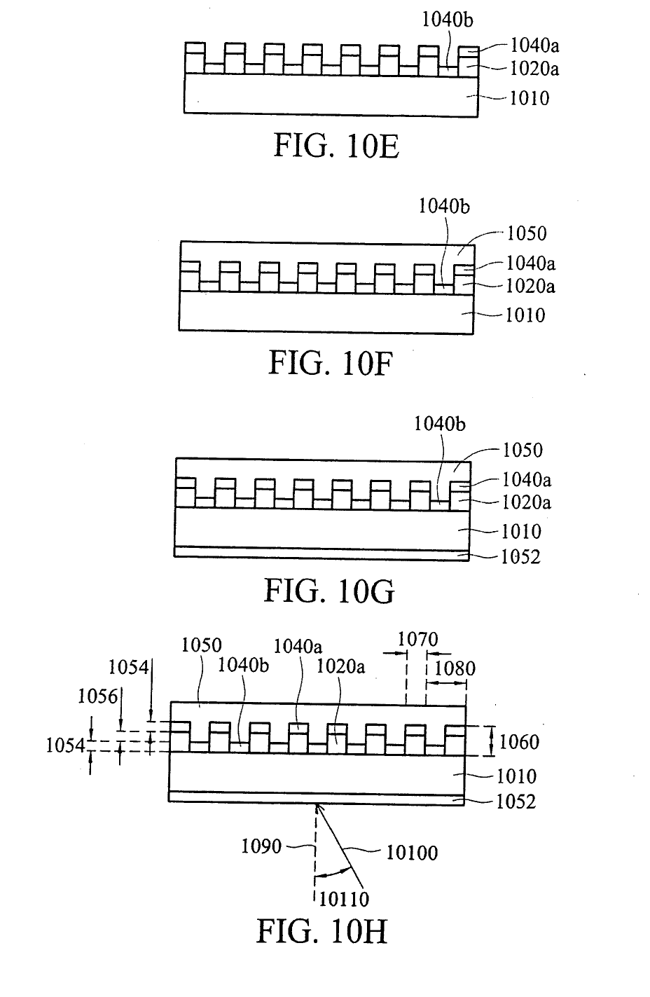

In FIG. 10A, a substrate 1010, such as a glass substrate, with a polymer layer 1020 formed thereon is provided. The polymer layer 1020 may be polymethyl methacrylate (PMMA).

In FIGS. 10A to 10B, a mold 1030 having a pattern of microstructure is pressed into the polymer layer 1020 and the polymer layer 1020 is heated above a glass transition temperature thereof, thereby transferring the pattern to the polymer layer 1020.

After removal of the mold 1030, a plurality of lands 1020a and grooves 1020b are formed in the polymer layer 1020, as shown in FIG. 10C.

In FIG. 10D, reactive ion etching removes residual portions of the polymer layer 1020 from the bottom of the grooves 1020b, thereby exposing surfaces of the substrate 1010.

In FIG. 10E, a first metal layer 1040a and second metal layer 1040b are concurrently formed on the lands 1020a and grooves 1020b, respectively, using sputtering or vacuum deposition. The first metal layer 1040a and second metal layer 1040b may be silver (Ag).

In FIG. 10F, a dielectric layer 1050 is formed on the first metal layer 1040a and second metal layer 1040b.

In FIG. 10G, a polarizer 1052 is disposed under the substrate 1010.

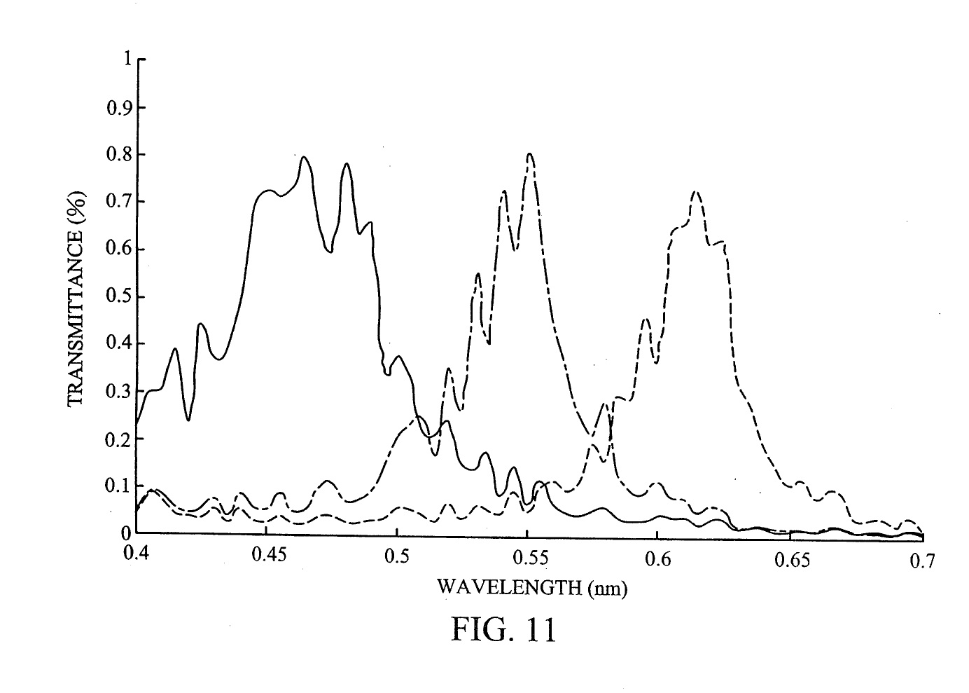

In addition, optical properties of the color filter of the embodiment are simulated by a commercial application called Gsolver. FIG. 11 is a chart showing the transmission spectrum for the color filter shown in FIG. 10H with an exemplary incident light 10100. The incident light 10100 has a wavelength between 400 and 700 nm, and an incident angle 10110. The substrate 1010 has a thickness of 1000 micrometers. One land 1020a and one groove 1020b have a total width 1080 of 200 nm. The lands 1020a have a uniform width 1070 of 100 nm. The first metal layer 1040a and second metal layer 1040b have a uniform thickness 1054, of 50, 60, or 60 nm. The first metal layer 1040a has a relative height 1056 exceeding that of the second metal layer 1040b, of 100, 133, or 160 nm.

As shown in FIG. 11, the transmission peaks occur at 470 (blue), 550 (green), and 610 nm (red), respectively.

In this embodiment, each color light has a transmission over 80% when the width 1080 shifts to 200 nm.

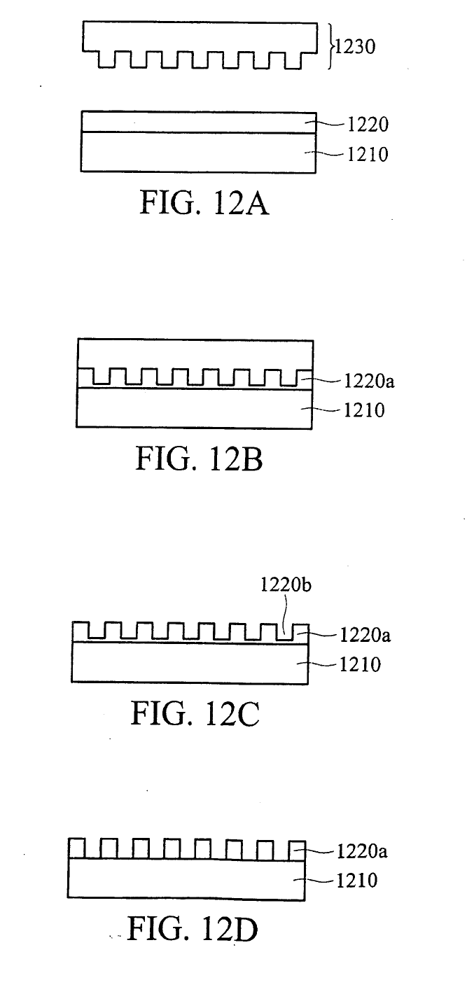

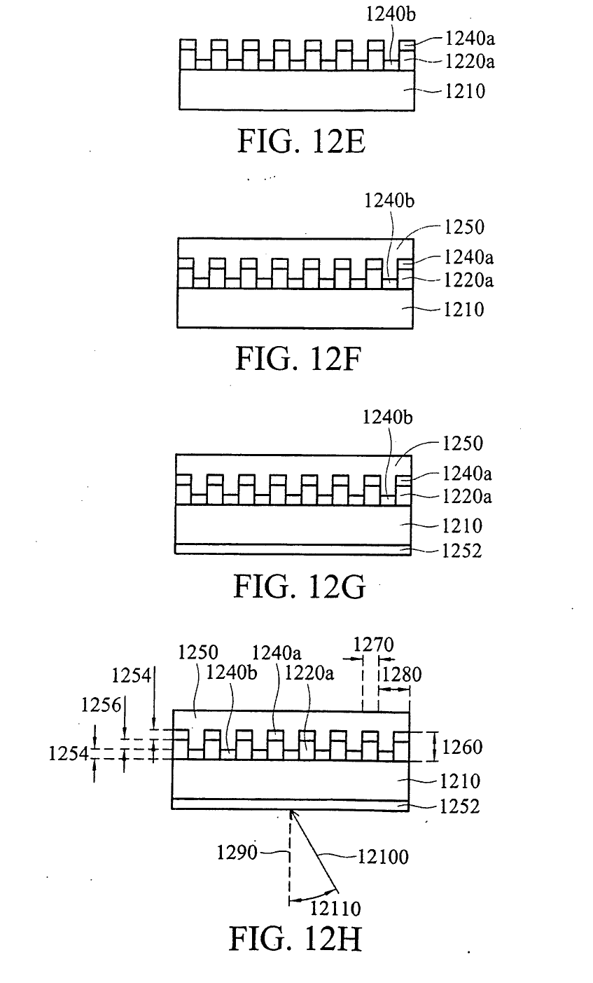

In FIG. 12A, a substrate 1210, such as a glass substrate, with a polymer layer 1220 thereon is provided. The polymer layer 1220 may be polymethyl methacrylate (PMMA).

In FIGS. 12A to 12B, a mold 1230 having a pattern of microstructure is pressed into the polymer layer 1220 and the polymer layer 1220 is heated above a glass transition temperature thereof, thereby transferring the pattern to the polymer layer 1220.

After removal of the mold 1230, a plurality of lands 1220a and grooves 1220b are formed in the polymer layer 1220, as shown in FIG. 12C.

In FIG. 12D, reactive ion etching removes residual portions of the polymer layer 1220 from the bottom of the grooves 1220b, thereby exposing surfaces of the substrate 1210.

In FIG. 12E, a first metal layer 1240a and second metal layer 1240b are concurrently formed on the lands 1220a and grooves 1220b, respectively, using sputtering or vacuum deposition. The first metal layer 1240a and second metal layer 1240b may be silver (Ag).

In FIG. 12F, a dielectric layer 1250 is formed on the first metal layer 1240a and second metal layer 1240b.

In FIG. 12G, a polarizer 1252 is disposed under the substrate 1210.

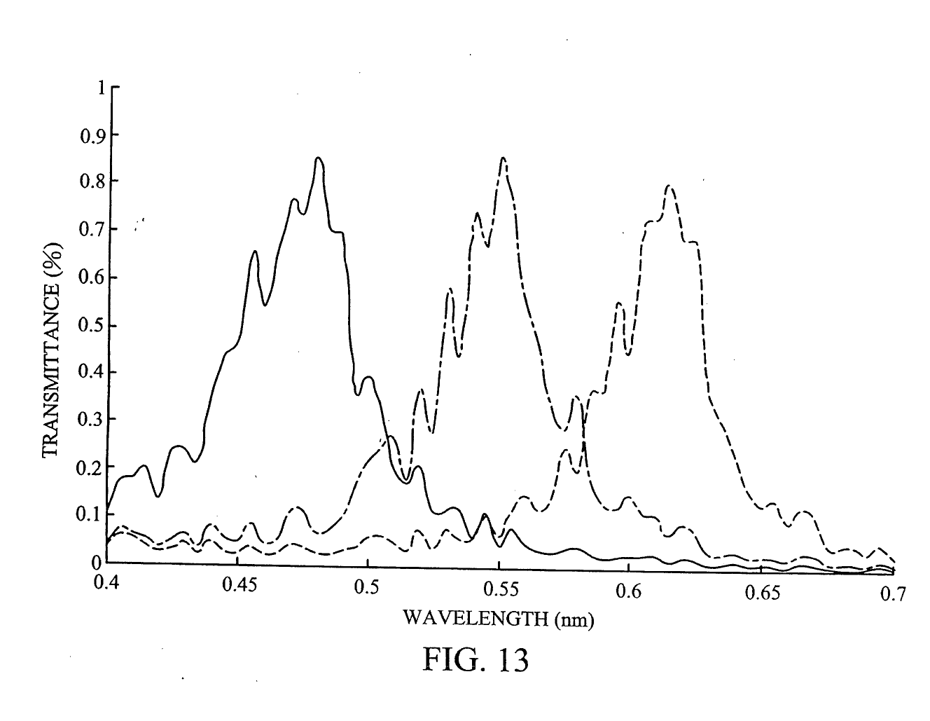

In addition, optical properties of the color filter of the embodiment are simulated by a commercial application called Gsolver. FIG. 13 is a chart showing the transmission spectrum for the color filter shown in FIG. 12H with an exemplary incident light 12100. The incident light 12100 has a wavelength between 400 and 700 nm, and an incident angle 1211. The substrate 1210 has a thickness of 1200 micrometers. One land 1220a and one groove 1220b have a total width 1280 of 150 nm. The lands 1220a have a uniform width 1270 of 75 nm. The first metal layer 1240a and second metal layer 1240b have a uniform thickness 1254, of 50, 50, or 50 nm. The first metal layer 1240a has a relative height 1256 exceeding that of the second metal layer 1240b, of 100, 140, or 165 nm.

As shown in FIG. 13, the transmission peaks occur at 470 (blue), 550 (green), 610 nm (red), respectively.

In this embodiment, each color light has a transmission approaching 90% when the width 1280 shifts to 150 nm.

In other embodiments, the second metal layer may be directly formed on the residual polymer layer in the grooves without etching.

Referring to FIG. 12, the color filter of the described embodiments comprises a substrate 1252, a polymer layer having a plurality of lands 1220a and grooves 1220b, a first metal layer 1240a disposed on the lands 1220a, a second metal layer 1240b disposed on the grooves 1220b or a polarizer 1252.

In FIG. 14A, a substrate 1410, such as a glass substrate, with a polymer layer 1420 formed thereon is provided. The polymer layer 1420 may be mr-L6000.3XP manufactured by micro resist technology Inc.

In FIGS. 14A to 14B, a mold 1430 having a pattern of microstructure is pressed into the polymer layer 1420 and the polymer layer 1420 is exposed under UV light, thereby transferring the pattern to the polymer layer 1420.

After removal of the mold 1430, a plurality of lands 1420a and grooves 1420b are formed in the polymer layer 1420, as shown in FIG. 14C.

In FIG. 14D, reactive ion etching removes residual portions of the polymer layer 1420 from the bottom of the grooves 1420b, thereby exposing surfaces of the substrate 1410.

In FIG. 14E, a first metal layer 1440a and second metal layer 1440b are concurrently formed on the lands 1420a and grooves 1420b, respectively, using sputtering or vacuum deposition.

In FIG. 14F, a dielectric layer 1450 is formed on the first metal layer 1440a and second metal layer 1440b.

In FIG. 14G, a polarizer 1452 is disposed under the substrate 1410.

In other embodiments, the second metal layer 1440b may be directly formed on the residual polymer layer in the grooves without etching.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of fabricating a color filter, comprising:
providing a substrate;
forming a polymer layer on the substrate;
forming a plurality of grooves and lands in the polymer layer;
forming a first metal layer on the lands; and
forming a second metal layer on the grooves.

2. The method as claimed in claim 1, wherein the substrate comprises glass or plastic.

3. The method as claimed in claim 1, wherein the polymer layer comprises polymethyl methacrylate (PMMA).

4. The method as claimed in claim 1, wherein formation of the grooves and lands comprises:
providing a mold having a pattern of microstructure; and
transferring the pattern to the polymer layer, thereby the lands and the grooves are formed concurrently therein, wherein the polymer layer is heated above a glass transition temperature thereof.

5. The method as claimed in claim 4, further comprising removal of residual polymer layer from the bottom of the grooves, exposing surfaces of the substrate.

6. The method as claimed in claim 5, wherein removal of the residual polymer layer from the bottom of the grooves comprises reactive ion etching.

7. The method as claimed in claim 1, wherein formation of the first metal layer on the lands and formation of the second metal layer on the grooves comprise sputtering or vacuum deposition.

8. The method as claimed in claim 1, further comprising formation of a dielectric layer on the first metal layer and the second metal layer.

9. The method as claimed in claim 1, wherein the polymer layer comprises a photosensitive polymer material.

10. The method as claimed in claim 1, wherein the step of forming the grooves and the lands in the polymer layer comprises:
providing a mask having a pattern of microstructure; and
transferring the pattern to the polymer layer, thereby the lands and the grooves are formed concurrently therein, wherein the polymer layer is heated above a glass transition temperature thereof.

11. The method as claimed in claim 10, further comprising removal of residual polymer layer from the bottom of the grooves, exposing surfaces of the substrate.

12. The method as claimed in claim 11, wherein removal of residual polymer layer from the bottom of the grooves comprises reactive ion etching.
